(19) United States
(12) Patent Application Publication
(10) Pub. No.: US 2006/0185589 A1
(43) Pub. Date: Aug. 24, 2006

(54) Silicon gas injector and method of making

(76) Inventors: Raanan Zehavi, Sunnyvale, CA (US); Reese Reynolds, Los Gatos, CA (US)

Correspondence Address: LAW OFFICES OF CHARLES GUENZER, P O BOX 60729, PALO ALTO, CA, 94306, US

(21) Appl. No.: 11/177,808

(22) Filed: Jul. 8, 2005

Related U.S. Application Data
(60) Provisional application No. 60/655,483, filed on Feb. 23, 2005.

(51) Int. Cl. C23C 16/00; B32B 37/00; F16K 51/00; F27D 5/00

(52) U.S. Cl. 118/715; 427/248.1; 432/6; 156/292; 251/155

(57) ABSTRACT

A gas injector tube usable in a batch thermal treatment oven including two silicon shells joined together with an adhesive formed of a fine silicon powder and a curable silica-forming agent, such as a spin-on glass, which is ultrasonically homogenized. The tube may have a gas outlet on its distal end or be sealed with a silicon cap and have side outlet holes formed along its side. The silicon injector tube may be used in combination with a silicon tower and a silicon liner so that all bulk parts within the furnace hot zone are formed of silicon.

### RELATED APPLICATION

This application claims benefit of provisional application 60/655,483, filed Feb. 23, 2005.

### FIELD OF THE INVENTION

The invention relates generally to thermal processing of semiconductor wafers. In particular, the invention relates to gas injectors in a thermal treatment furnace.

### BACKGROUND ART

Batch thermal processing continues to be used for several stages in the fabrication of silicon integrated circuits. One low temperature thermal process deposits a layer of silicon nitride by chemical vapor deposition, typically using chlorosilane and ammonia as the precursor gases at temperatures in the range of about 700° C. Other low-temperature processes include the deposition of polysilicon or silicon dioxide or other processes utilizing lower temperatures. High-temperature processes include oxidation, annealing, silicidation, and other processes typically using higher temperatures, for example above 1000° C. or even 1200° C.

Large-scale commercial production typically uses vertical furnaces and vertically arranged wafer towers supporting a large number of wafers in the furnace, often in a configuration illustrated in the schematic cross-sectional view of FIG. 1. The furnace includes a thermally insulating heater canister 12 supporting a resistive heating coil 14 powered by an unillustrated electrical power supply. A bell jar 16, typically composed of quartz, includes a roof and fits within the heating coil 14. An open-ended liner 18 may be used, which fits within the bell jar 16. A support tower 20 sits on a pedestal 22 and during processing the pedestal 22 and support tower 20 are generally surrounded by the liner 18. The tower 20 includes vertically arranged slots for holding multiple horizontally disposed wafers to be thermally processed in batch mode. A gas injector 24 principally disposed between the tower 20 and the liner 19 has an outlet on its upper end for injecting processing gas within the liner 18. An unillustrated vacuum pump removes the processing gas through the bottom of the bell jar 16. The heater canister 12, bell jar 16, and liner 18 may be raised vertically to allow wafers to be transferred to and from the tower 20, although in some configurations these elements remain stationary while an elevator raises and lowers the pedestal 22 and loaded tower 20 into and out of the bottom of furnace 10.

The bell jar 18 closed on its upper end causes the furnace 10 to tend to have a generally uniformly hot temperature in the middle and upper portions of the furnace. This is referred to as the hot zone in which the temperature is controlled for the optimized thermal process. However, the open bottom end of the bell jar 18 and the mechanical support of the pedestal 22 cause the lower end of the furnace to have a lower temperature, often low enough that the process such as chemical vapor deposition is not completely effective. The hot zone may exclude some of the lower slots of the tower 20.

Conventionally in low-temperature applications, the tower, liner, and injectors have been composed of quartz or fused silica. However, quartz towers and injectors are being supplanted by silicon towers and injectors. One configuration of a silicon tower available from Integrated Materials, Inc. of Sunnyvale, Calif. is illustrated in the orthographic view of FIG. 2. The fabrication of such a tower is described by Boyle et al. in U.S. Pat. No. 6,455,395, incorporated herein by reference. Silicon liners have been proposed by Boyle et al. in U.S. patent application Ser. No. 09/860,392, filed May 18, 2001.

Silicon injectors have been commercially available from Integrated Materials. However, they have used a lead-based adhesive between the two shells forming the long straw. Even though the amount of lead is relatively low, it is strongly desired to completely avoid its use in a processing furnace where the lead may seriously degrade the semiconducting silicon structure being developed. The gluing of the two shells also presents a challenge to make the seam leak tight along its long length.

### SUMMARY OF THE INVENTION

The invention includes a silicon injector system usable in a furnace in which an injector tube or straw is composed of two shells of silicon joined together with a spin-on glass (SOG)-based adhesives, preferably including silicon powder. The invention also includes a silicon elbow and supply tube joined together with such a SOG-based adhesive.

The invention further includes the method of fabricating such a silicon injector system.

Another aspect of the invention includes ultrasonically agitating a mixture of the silica-forming agent and silicon powder to thereby homogenize it into a SOG-based adhesive before it is applied to the silicon parts to be joined and annealed.

The invention yet further includes an annealing furnace having an all-silicon hot zone including tower, injectors, and baffle wafers and its use in fabricating silicon integrated circuits.

### BRIEF DESCRIPTION OF THE DRAWINGS

FIG. 1 is a cross-sectional view of an annealing oven enclosing a tower, injector tube, and liner.

FIG. 2 is an orthographic view of one embodiment of an injector tube of the invention having an end outlet.

FIG. 3 is an orthographic view of the connector part of the injector tube of FIG. 2.

FIG. 4 is an exploded orthographic view of the outlet end of the injector tube of FIG. 2.

FIG. 5 is an orthographic view of a shell used to form one embodiment of the injector tube of the invention.

FIG. 5 is a cross-sectional view of two shells preparatory to bonding.

FIG. 6 is a cross-sectional view of the bonded shells of FIG. 5 in one embodiment of the shells.

FIGS. 7 through 10 are cross-sectional view of different forms of the interface between joined shells in other embodiments of the shells.

FIG. 11 is an orthographic view of another embodiment of an injector tube of the invention having multiple side outlets.

FIG. 12 is an orthographic view of a jig used in fusing the parts of the injector tube.

### DETAILED DESCRIPTION OF THE PREFERRED EMBODIMENTS

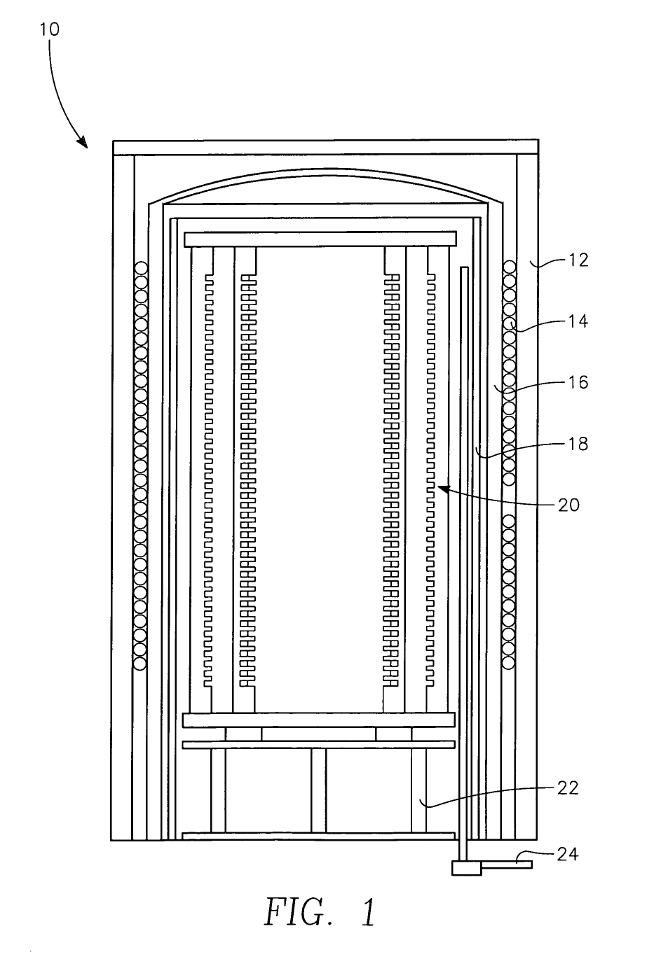

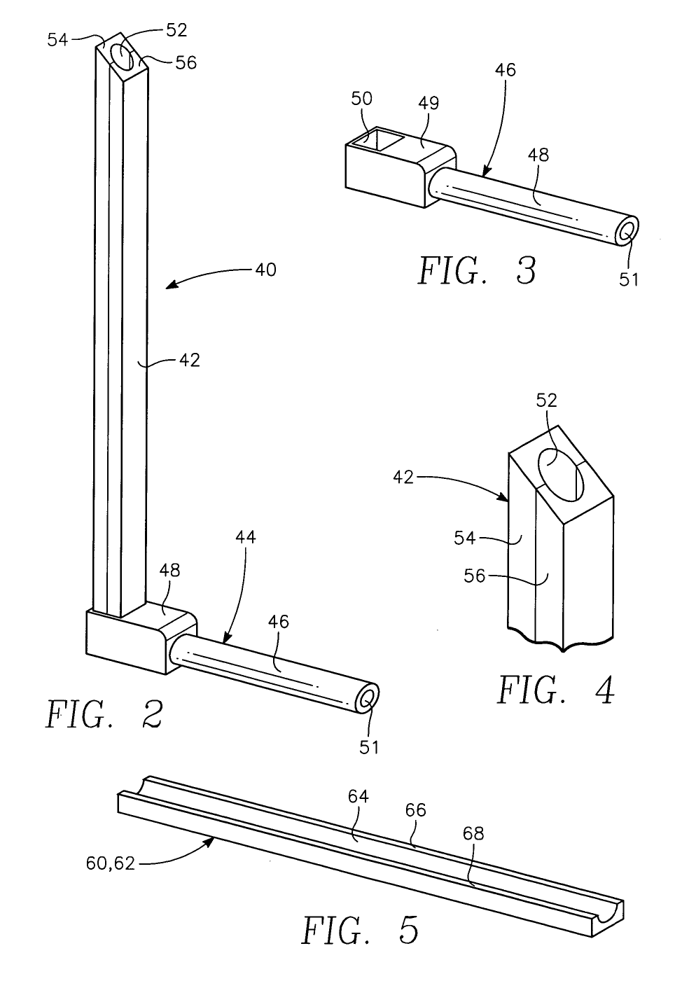

One embodiment of an injector 40 of the invention illustrated in the orthographic view of FIG. 1 includes an injector straw 42 (also referred to as a tube) and a knuckle 44 (also known as a connector). The knuckle 46, illustrated in more detail in the orthographic view of FIG. 3, includes a supply tube 48 and an elbow 49 having a recess 50 to receive the injector straw 42. The supply tube 48 may have an outer diameter of approximately 4 to 8 mm with a correspondingly sized inner circular bore 51.

The end of the supply tube 48 may be connected through a vacuum fitting and O-ring to a gas supply line supplying the desired gas or gas mixture into the furnace, for example, ammonia and silane for the CVD deposition of silicon nitride. The entire integral knuckle 46 may be machined from annealed virgin polysilicon according to the process described by Boyle et al. in U.S. Pat. No. 6,450,346. The machining includes connecting the supply bore 51 to the recess 20. Alternatively, the knuckle 44 may assembled from a separate tube 48 fit into and bonded to the separately machined elbow 49.

The injector straw 42 is formed with a circular injector bore 52, for example, having a diameter similar to that of the circular bore 52 of the tube 46 extending along its entire length. The injector straw 42 may have a beveled end, as illustrated, for example facing the chamber liner or it may have a flat end perpendicular to the axis of the straw 42. The cross-sectional shape of the injector straw 42 may be substantially square, as illustrated, or may be octagonal or round or be otherwise shaped depending upon the requirements of the furnace maker and the fab line. The injector straw 42 is composed of two shells 54, 56, which are joined together. The shells 54, 56 may slanted distal ends such that the outlet of the bore 52, illustrated in more detail in the orthographic view of FIG. 4, is partially directed to the side, for example, towards the liner 18 in its operational orientation.

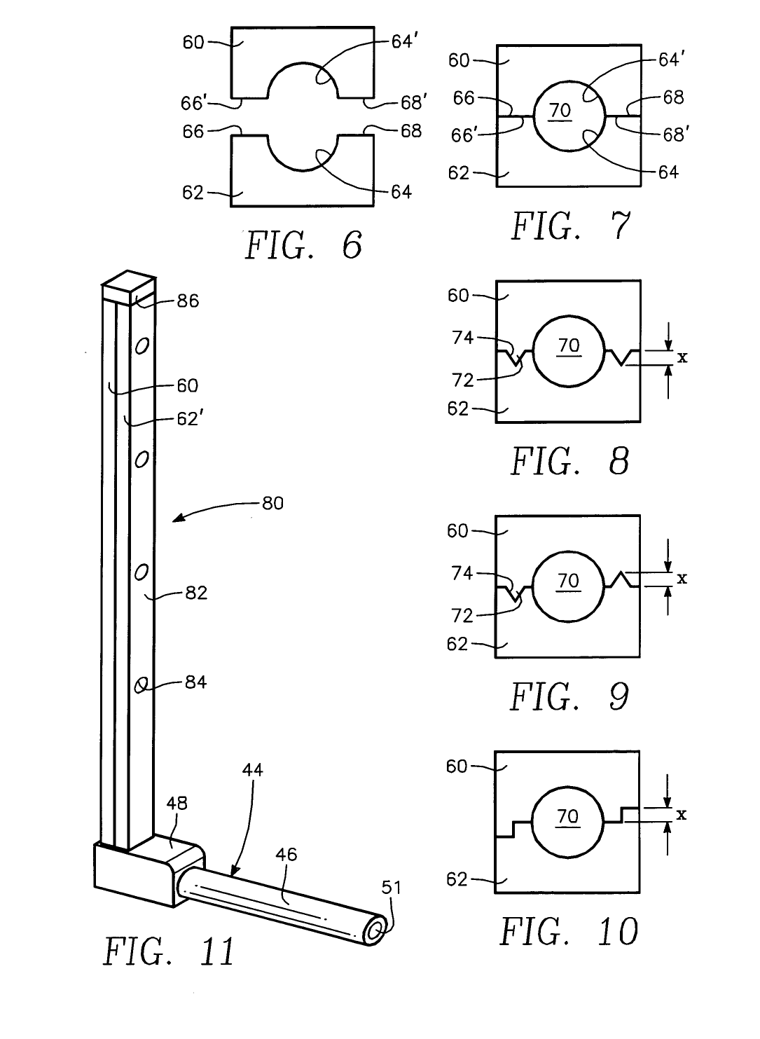

Alternatively, the straw 42 may have a perpendicular outlet, composed of two shells 60, 62 (or 54, 56), one of which is orthographically illustrated in FIG. 5. Each shell 60, 62 is machined from virgin polysilicon after the anneal described in the Boyle patent to include a semi-circular or other shaped groove 64 and two longitudinally extending faces 66, 68. It is possible to form the shells 60, 62, as further shown in the cross-sectional view of FIG. 6 for both shells 60, 62 with respective opposed faces 66, 68, 66′, 68′, which when bonded together, as shown in the cross-sectional view of FIG. 7, enclose an axial bore 70. However, a feature orthogonal to the plane of joining improves the durability of the bond. Such a feature may be, for example, by a tongue-and-groove structure shown in the cross-sectional view of FIG. 8 with two axially extending tongues 72 formed in one shell 60 mating with two axially extending grooves 74 formed in the other shell 62. A related structure shown in the cross-sectional view of FIG. 9 forms one tongue 72 and one groove 74 in each of the mating shells 60, 62. Alternatively, a stepped structure shown in the cross-sectional view of FIG. 10 includes complementary and corresponding steps 76 formed in each of the shells 60, 62, preferably with the level of the step 76 adjacent the bore 70 being approximately along the bore diameter. The groove depth or step height x should be greater than the maximum diameter of the fusing particles, for example, greater than 10 or 100 μm.

The injector tube 40 of FIG. 2 includes a single outlet at its distal end. In some applications, one such injector tube extending to near the top of the tower 20 of FIG. 1 may suffice. In other applications, it may be desired to inject gas at multiple heights along the tower 20. In this case, multiple injectors tubes 40 of different lengths may be used in the same furnace 10. However, in another embodiment of a injector 80, illustrated in the orthographic view of FIG. 11, its straw 82 includes two square-ended sleeves 60, 62′ similar to those of FIG. 5 with selected faces chosen from the embodiments of FIGS. 7 through 10. However, the sleeve 62′, for example, the outwardly facing one, is machined to include at least one and preferably a plurality of outlet holes 84 extending from the exposed shell face to the bore 70 enclosed within the straw 82. Most easily, the outlet holes 84 are drilled to have a round shape. The sleeves 60, 62′ are bonded together and a silicon end cap 86 is bonded to the distal ends of the shells 60, 62′ to seal the bore 70. Thereby, gas is ejected laterally from the one or more outlet holes 84. If there are multiple outlet holes 84, the gas is ejected at different heights within the oven. In the simplest embodiment of multiple outlet holes 84, particularly three and more, the outlet holes 84 have a same diameter and are equally spaced along an operational part of the straw 82. However, gas flow can be tailored by varying their diameters or their spacing along the straw 82, for example exponentially, to account for pressure drop in the straw 82 and the pumping differential within the oven 10 as well as for other effects.

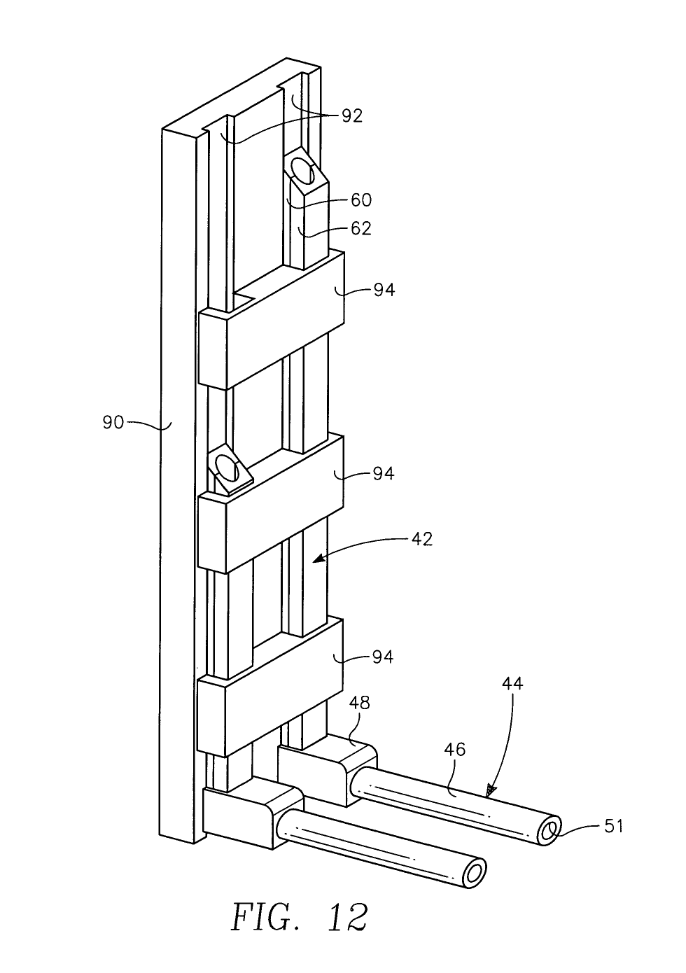

The injectors may be assembled and glued using a jig 90, illustrated in the orthographic view of FIG. 12, which may be oriented vertically or horizontally during different steps of injector assembly. The jig 90 has one or more horizontally extending grooves 72 shaped to receive at least the bottom shell 60 and the elbow 44. However, the jig can be equally well applied to other forms of shells. A nano-powder spin-on glass (SOG) adhesive is applied along either both of the opposing pairs of faces 66, 68 or along one face 66 of each pair and powderless SOG is applied along to and wets the other face. The wetting layer of powderless SOG or other wetting agent may be applied to the faces prior to the application of the Si-powder SOG. The nano-powder allows a very thin and continuous leak-tight seal between the two shells 60, 62. The two shells 60, 62 are pressed together. In one method of gluing, the shells are placed into the grooves 92 of the jig 90. The jig 90 and supported shells 60, 62 are is placed in a horizontal furnace with the jig 90 extending horizontally. Thereby, the SOG adhesive is annealed and the sleeves 60, 62 are bonded to form the straw 42.

After curing of the adhesive, a powder-containing SOG adhesive is applied one or to both surfaces of the joint between the straw 42 and the knuckle 44 and the straw 42 is placed into the recess 50 of the elbow 48. A micro-powder SOG glue may be used to provide a thicker bond at the knuckle joint and to prevent the thinner nano-powder SOG glue from leaking out during annealing and bonding the assembly to the jig 90, but with proper care a nano-powder SOG glue may be used for the knuckle joint. If the end cap 86 is being applied, it may be similarly glued at this time or at some other time. The assembly is then placed back on the jig 90, which is then placed in a vertical furnace with the jig 90 extending vertically to be cured into the final injector 40. In a second method, the jig is redesigned to avoid the leakage problem and the uncured straw 42 is glued into the knuckle 44 and all joints are annealed at the same time. If the jig accommodates multiple injectors, the assembly is replicated for all injectors. Multiple guides 94 are placed over the assembled sleeves 60, 62 to hold them in their respective groove 92. Preferably, both the jig 90 and guides 94 are composed of silicon. Virgin polysilicon is not required but is economically used.

The micro-powder and nano-powder silicon SOG adhesives are described in more detail in U.S. patent application Ser. No. 10/670,990, filed Sep. 25, 2003, now published as Patent Application Publication 2004/213955, incorporated herein by reference. The micro-powder can be ground from commercially available silicon powder and is estimated to have a size distribution with 99% of all particles having diameters of less than 75 μm and with care less than 10 μm. The nano-silicon powder is available as NanoSi™ Polysilicon from Advanced Silicon Materials LLC of Silver Bow, Mont. It may be produced by a reduction process involving laser activation and has a particle size distribution with at least 99% of all particles having diameters of less than 100 nm; at least 90%, less than 50 nm, and a median size of between 10 and 25 nm. However, the nano-silicon powder may be made in other ways. The silicon powder is mixed with a spin-on glass (SOG) precursor, such as FOX 25 or FOX 16 available from Dow Corning. These precursors are based on hydrogen silesquixoane (HSQ) although other forms of siloxanes and other forms of glass-forming agents may be used. A plastic test tube containing the mixture of SOG precursor and powder is placed in an ultrasonic bath apparatus to subject the mixture to ultrasonic agitation for two or three minutes to thereby homogenize the mixture. The ultrasonic bath apparatus may include piezoelectric transducers adjacent a water bath and electrically driven at a high frequency, for example, 40 kHz, although frequencies up into the megahertz range may be used. The SOG adhesive mixture, preferably already homogenized although it is possible to homogenize after application, is applied to the one or both faces of the joint and the parts are mated. The assembled structure is annealed at an elevated temperature sufficient to glassify the silica-forming agent into a ceramic and to bond the two parts together. Various annealing temperatures are possible depending upon the form of the SOG adhesive. However, it has been found preferable to anneal at between 850 to 1000° C., for example, near 900° C.

The silicon injector allows the hot zone within the liner to be occupied solely by silicon bulk material and parts, aside from thin layers of deposited materials formed on the production wafers and other silicon parts in the hot zone and perhaps small amounts of bonding agents such as the SOG-based adhesive. The bulk part of the liner, the support tower, and the injectors are composed of pure silicon except for the SOG adhesive although they may be covered by thin surface layers, for example, of silicon nitride or the like. Baffle wafers are often placed in empty slots of the tower to fill out a production run or to provide thermal buffering. The baffle wafers, as explained by Boyle et al. in provisional application 60/658,075, filed Mar. 3, 2005, may be composed of silicon, preferably polycrystalline silicon, and most preferably randomly oriented Czochralski polysilicon.

Depending on the annealing or thermal treatment being done in the furnace, one injector may be sufficient or multiple injectors may be used having different heights within the furnace.

The invention is not limited to the illustrated injector. For example, the straw could be formed with a base machined with a bore and a near planar cover bonded to it. Further, one or more injector jets could extend laterally from a substantially enclosed bore extending the axis of the injector rather than from the end of the straw.

The SOG adhesive aspects of the invention may be used to join silicon parts other than silicon injectors.

1. A silicon gas injector comprising an injector tube formed of two shells comprising substantially pure silicon bonded together with an adhesive formed of silicon powder and a silica-forming agent and forming a first central bore therebetween.

2. The injector of claim 1, further comprising a second silicon tube assembly bonded to the two shells with an adhesive formed of silicon powder and a silica-form agent and including a supply tube extending perpendicularly to the injector tube and including a second central bore communicating with the first central bore.

3. The injector of claim 1, wherein the silicon powder has a size distribution with 99% of all particles having diameters of less than 75 μm.

4. The injector of claim 3, wherein size distribution has 99% of all the particles having diameters of less than 10 μm

5. The injector of claim 4, wherein the size distribution has 99% of all the particles having diameters of less than 100 nm.

6. The injector of claim 2, wherein the second silicon tube assembly includes the supply tube and an elbow formed as an integral unit.

7. The injector of claim 1, wherein the two shells are formed of virgin polysilicon.

8. The injector of claim 1, wherein the two shells comprise mating tongues and grooves at interfaces therebetween.

9. The injector of claim 1, wherein the two shells comprises mating steps at interfaces therebetween.

10. The injector of claim 1, wherein the two shells comprise mating stepped surfaces at interfaces therebetween.

11. The injector of claim 1, further comprising a cap sealed to an end of the bonded shells and further comprising at least one holes formed in an axially extending side of one of the shells and extending to a bore of the tube.

12. The injector of claim 11, wherein there are a plurality of the holes axially spaced along the axially extending side.

13. The injector of claim 12, wherein diameters of the holes or spacings between at least three of the holes varies along the axially extending side.

14. A method of assembling a gas injector, comprising the steps of:
providing two shells comprising substantially pure silicon and forming an axial bore therebetween when assembled together;
applying an adhesive comprising silicon powder and a curable silica-forming agent to at least some mating faces of the two shells;
assembling the two shells by juxtaposing respective mating faces of the two shells; and
annealing the assembled shells at a temperature of at a temperature sufficient to glassify adhesive.

15. The method of claim 14, wherein the temperature is least 400° C.

16. The method of claim 15, wherein the temperature is between 850 and 1000° C.

17. The method of claim 14, wherein the providing step includes:
machining the shells from at least one annealed virgin polysilicon member.

18. The method of claim 14, further comprising applying a powder-free wetting agent to at least some of the mating faces prior to applying the adhesive.

19. The method of claim 18, wherein the wetting agent comprises a curable silica-forming agent.

20. The method of claim 14, further comprising:
mixture the silica-forming agent and the silicon powder into a mixture; and
ultrasonically agitating the mixture to form the adhesive.

21. A method of bonding together two silicon parts, comprising the steps of:
mixing together silicon powder and a silica-forming agent;
ultrasonically agitating the mixture;
applying the agitated mixture to at least one of two mating surface of two respective silicon members; and
joining the silicon members along the two mating surfaces with the agitated mixture therebetween.

22. The method of claim 21, further comprising annealing the joined silicon members to thereby cure the silica-forming agent.

23. A method of thermally treating silicon wafers, comprising:
supporting silicon production wafers on a silicon tower;
disposing the silicon tower and the wafers supported thereupon in a furnace including a silicon liner surrounding the tower; and
flowing a process gas through at least one silicon injector having an outlet disposed between the tower and the liner to treat the production wafers in a hot zone of the furnace within the liner;
wherein all bulk portions of the tower, the liner, and the injector disposed within the hot zone are substantially free of material other than silicon and excluding any lead-based adhesive for the injector.

24. The method of claim 23, wherein the injector comprises a tube formed of two substantially pure silicon shells bonded together with an adhesive formed of silicon powder and a silica-forming agent and forming a central axial bore therebetween.
